(19) United States
(12) Patent Application Publication
(10) Pub. No.: US 2015/0000740 A1
(43) Pub. Date: Jan. 1, 2015

(54) SOLAR CELL MODULE

(71) Applicant: SHARP KABUSHIKI KAISHA, Osaka-shi, Osaka (JP)

(72) Inventor: Kazuhiro Mizuo, Osaka-shi (JP)

(21) Appl. No.: 14/370,930

(22) PCT Filed: Nov. 12, 2012
(86) PCT No.: PCT/JP2012/079216

§ 371 Date: Jul. 7, 2014

(30) Foreign Application Priority Data
Jan. 17, 2012 (JP) 2012-006943

(51) Int. Cl. H01L 31/042; H01L 31/048

(52) U.S. Cl. CPC H01L 31/0422; H01L 31/0488
USPC 136/259

(57) ABSTRACT

A solar cell module for ensuring the thickness of an adhesive material and enhancing adhesion strength is provided by devising a configuration of an adhesion surface of a support member. The solar cell module is equipped with an elongated support member (20) and a solar cell main body having a laminated glass structure. The solar cell main body includes a light-receiving glass, a backside glass, and a solar cell for photoelectrically converting sunlight, the solar cell being laid between the light-receiving glass and the backside glass. The support member (20) is fixedly bonded on a surface of the backside glass by an adhesive material. The support member (20) has a recess (25) formed in an adhesion surface (21a) of the support member (20) to be bonded to the backside glass.

### TECHNICAL FIELD

The present invention relates to a solar cell module comprising a solar cell main body having a laminated glass structure, wherein the solar cell main body comprises a solar cell for photoelectrically converting sunlight, a light-receiving glass, and a backside glass, with the solar cell laid between the light-receiving glass and the backside glass. More particularly, the present invention relates to a solar cell module equipped with an elongated support member (mounting rail).

### BACKGROUND ART

Conventionally, there has been provided a solar cell module equipped with mounting rails as support members for mounting the solar cell module on a rack (for example, see PTL 1). The support members are employed not only for the purpose of mounting the solar cell module on a rack or the like, and also for the purpose of increasing the strength of the solar cell module itself.

For a solar cell module equipped with such mounting rails, it is important to ensure long-term reliability in an adhesion part at which the support members in the form of the mounting rails are bonded to the backside glass of the solar cell module.

In this regard, PTL 1 principally focuses on an adhesive agent for a solar cell module such that the solar cell module can withstand a shearing stress at the adhesion part when the solar cell module is deflected under an external force such as a snow load, or can withstand a thermal stress due to a difference in thermal expansion rate between a backside protection material and the support members in the solar cell module.

To describe it concretely, the solar cell module disclosed in PTL 1 is composed of a main body part which includes: a packing material composed of a first packing material on the light-receiving face side of the solar cell element and a second packing material on the non-light-receiving face side, the packing material being for holding solar cell elements between the first and second packing materials; a rod-like support member for supporting the main body part from the non-light-receiving face side; and a resin layer provided between the main body part and the support member. The solar cell module is configured to satisfy the relationship (G1/L1)<(G2/L2), wherein G1 is an elastic modulus of the resin layer, L1 is a thickness of the resin layer, G2 is an elastic modulus of the second packing material, and L2 is a thickness of the second packing material. The resin layer is composed of first resin layers and second resin layers whose elastic modulus is smaller than that of the first resin layer, with the first resin layers and the second resin layers being arranged alternately along the support member. The thus configured solar cell module maintains the thickness of the first resin layers during curing by utilizing the second resin layers as spacers, and thereby adjusts the first resin layers to a desired thickness.

### CITATION LIST

### Patent Literature

[PTL 1] JP 2011-109072 A

### SUMMARY OF INVENTION

### Technical Problem

In the conventional solar cell module described above, the adhesive material needs to have a certain elastic modulus. Besides, in order to ensure the thickness of the resin layer as the adhesive material, the resin layer needs to be made of the first resin layers and the second resin layers, and the thickness of the first resin layers needs to be ensured by the second resin layers which serve as spacers. Disadvantageously, these requirements necessitate a complex configuration and a complicated adhesion process.

The present invention has been made in order to solve these problems. An object of the present invention is to provide a solar cell module which can ensure the thickness of an adhesive material and can enhance adhesion strength by devising a configuration of an adhesion surface of a support member.

### Solution to Problem

In order to solve the above-mentioned problems, the present invention provides a solar cell module which is equipped with a solar cell main body having a laminated glass structure composed of a solar cell for photoelectrically converting sunlight, a light-receiving glass, and a backside glass, with the solar cell laid between the light-receiving glass and the backside glass. The solar cell module is characterized in that an elongated support member is fixedly bonded on a surface of the backside glass by an adhesive material, and that the support member has a recess formed in an adhesion surface thereof to be bonded to the backside glass. Namely, the solar cell module according to the present invention is characterized in including an elongated support member and a solar cell main body having a laminated glass structure, and is also characterized in that the solar cell main body has a light-receiving glass, a backside glass, and a solar cell for photoelectrically converting sunlight, the solar cell being laid between the light-receiving glass and the backside glass, that the support member is fixedly bonded on a surface of the backside glass by an adhesive material, and that the support member has a recess formed in an adhesion surface of the support member to be bonded to the backside glass.

Owing to this configuration, the recess provided in the adhesion surface can ensure the thickness of the adhesive material applied between the adhesion surface of the support member and the backside glass, and can thereby enhance the adhesion force.

In the solar cell module according to the present invention, the recess is provided to extend along a longitudinal direction of the support member. The recess provided to extend along a longitudinal direction of the support member can ensure uniform adhesion strength in the longitudinal directions of the solar cell module.

In the solar cell module according to the present invention, the recess may be formed by a er first recess formed on a central portion of the support member in a width direction that is orthogonal to the longitudinal direction, and by a pair of shallower second recesses respectively formed on both sides of the first recess and parallel to the first recess. In other words, the recess may include a er first recess formed on a central portion of the support member in a width direction that is orthogonal to the longitudinal direction, and a pair of shallower second recesses respectively formed on both sides of the first recess and parallel to the first recess.

Owing to the recess composed of the er first recess and the shallower second recesses respectively formed on both sides thereof, when the support member is bonded to the backside glass, the adhesive material which runs over from the first recess can be stopped in the second recesses. Thus, it is possible to prevent the adhesive material from running over from the longitudinal edges of the support member.

In the solar cell module according to the present invention, the recess may be formed by a first recess formed on a central portion of the support member in a width direction that is orthogonal to the longitudinal direction, and by a second recess formed in a bottom surface of the first recess and being deeper than the first recess. In other words, the recess may include a first recess formed on a central portion of the support member in a width direction that is orthogonal to the longitudinal direction, and a second recess formed in a bottom surface of the first recess and being deeper than the first recess.

The recess composed of the first recess and the deeper second recess can better ensure the thickness of the adhesive material applied to the adhesion surface, and can therefore enhance the adhesion force.

In the solar cell module according to the present invention, the recess may be composed of a pair of recesses respectively formed on both edge portions of the support member in a width direction that is orthogonal to the longitudinal direction. The recesses formed along the widthwise edge portions can ensure uniform adhesion strength in the width directions of the solar cell module.

In the solar cell module according to the present invention, the recess may be composed of a plurality of recesses which align transversely or obliquely relative to the longitudinal direction of the support member. The recesses which are aligned transversely or obliquely relative to the longitudinal direction of the support member can ensure sufficient strength to withstand the stress due to a difference in thermal expansion between the support member and the backside glass caused by the heat or the like after the solar cell module is mounted.

In the solar cell module according to the present invention, the plurality of recesses may be spaced from each other at a predetermined interval over a whole length in the longitudinal direction of the support member. The recesses which are spaced from each other at a predetermined interval over a whole length in the longitudinal direction can contribute to uniform adhesion strength in the longitudinal direction of the solar cell module.

In the solar cell module according to the present invention, the recess may have a groove shape. The groove-shaped recess can be easily formed by extrusion molding of the support member made of, for example, aluminum.

In the solar cell module according to the present invention, a bottom surface of the recess may have a bumpy shape. The recess having a bumpy bottom surface can increase an adhesion area of the support member and the adhesive material and can also increase the thickness of the adhesive material, thereby enhancing the adhesion force.

In the solar cell module according to the present invention, the adhesive material may be a one-component or two-component silicone adhesive. As the adhesive material, a one-component or two-component silicone adhesive enables firm fixing of the support member on the backside glass of the solar cell module.

### Advantageous Effects of the Invention

Owing to the above-described configurations, the present invention can ensure the thickness of an adhesive material applied between the adhesion surface of the support member and the backside glass, and can thereby enhance the adhesion force. Eventually, it is possible to enhance long-term reliability in the solar cell module.

### BRIEF DESCRIPTION OF DRAWINGS

FIG. 1 is a perspective view showing an overall configuration of a solar cell system, with solar cell modules mounted on a rack.

FIG. 2 is a perspective view of the solar cell module as seen from the light-receiving face side.

FIG. 3 is a perspective view of the solar cell module as seen from a backside thereof, opposite to the light-receiving face side.

FIG. 4 is an exploded perspective view of e solar cell module as seen from the backside.

FIG. 5 is a perspective view of a support member which constitutes the solar cell module.

FIG. 6 is a cross section taken along the line A-A in FIG. 5.

FIG. 7 is a perspective view of the solar cell module, showing around an end of the support member on an enlarged scale.

FIG. 8 is a cross section in which the support member is fixedly bonded on the backside glass of the solar cell module.

FIG. 9A is a cross section of a recess according to Alternative Configuration Example 1.

FIG. 9B is a cross section in which the support member is fixedly bonded on the backside glass of the solar cell module according to Alternative Configuration Example 1.

FIG. 10A is a cross section of a recess according to Alternative Configuration Example 2.

FIG. 10B is a cross section in which the support member is fixedly bonded on the backside glass of the solar cell module according to Alternative Configuration Example 2.

FIG. 11A is a cross section of recesses according to Alternative Configuration Example 3.

FIG. 11B is a cross section in which the support member is fixedly bonded on the backside glass of the solar cell module according to Alternative Configuration Example 3.

FIG. 12A is a plan view of recesses according to Alternative Configuration Example 4.

FIG. 12B is a perspective view of the recesses according to Alternative Configuration Example 4.

FIG. 13A is a plan view of recesses according to Alternative Configuration Example 5.

FIG. 13B is a perspective view of the recesses according to Alternative Configuration Example 5.

FIG. 14A is a cross section of recesses according to Alternative Configuration Example 6.

FIG. 14B is a cross section of recesses according to Alternative Configuration Example 7.

FIG. 15 is a perspective view showing a support structure wherein the support member is attached to a horizontal crosspiece of a rack by means of a mounting fitting.

FIG. 16 is a cross section showing the support structure in FIG. 15.

### DESCRIPTION OF EMBODIMENTS

Hereinafter, embodiments of the present invention are described with reference to the drawings.

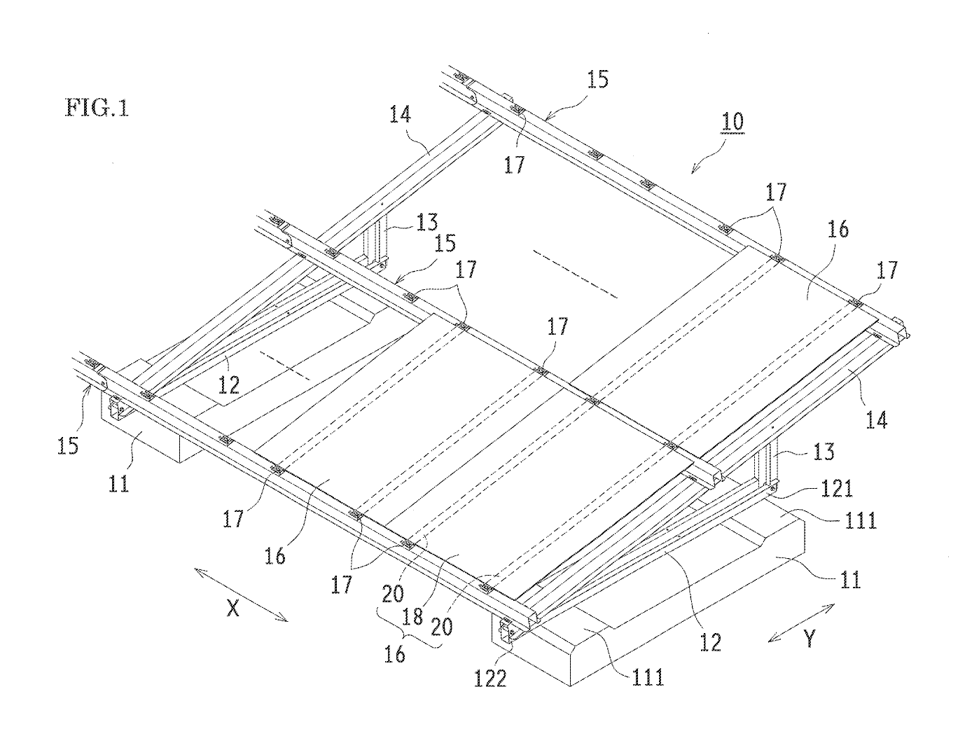

FIG. 1 is a perspective view showing an overall configuration of a solar cell system, with a plurality of solar cell modules 16 according to the present invention being mounted on a rack 10.

The photovoltaic system in this embodiment is configured to be utilizable, for example, as a power plant. Broadly speaking, the rack 10 is composed of concrete foundations 11, base crosspieces 12, arms 13, vertical crosspieces 14, and horizontal crosspieces 15.

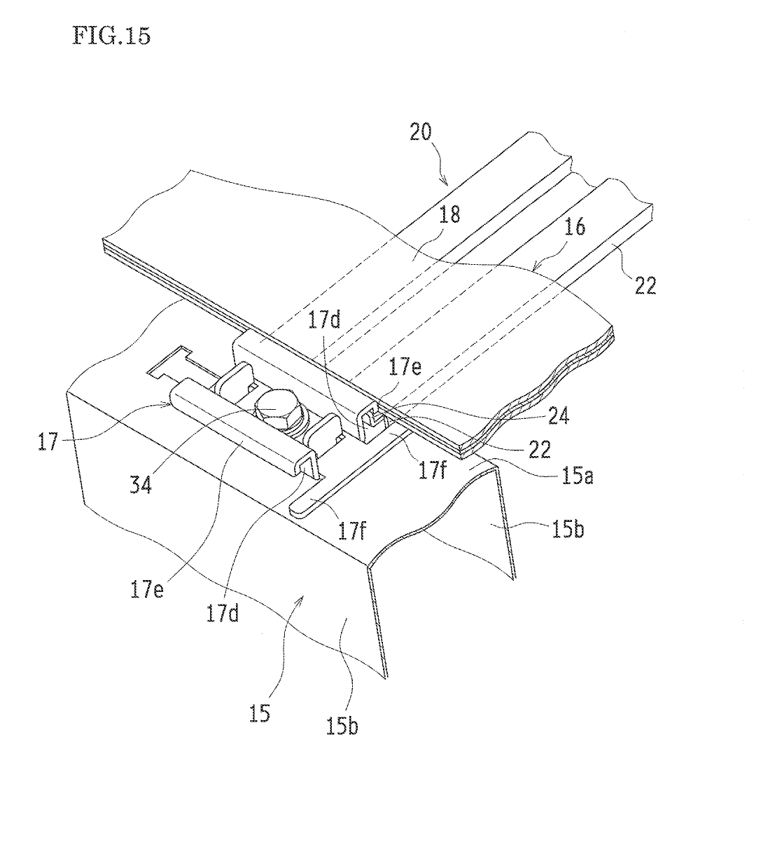

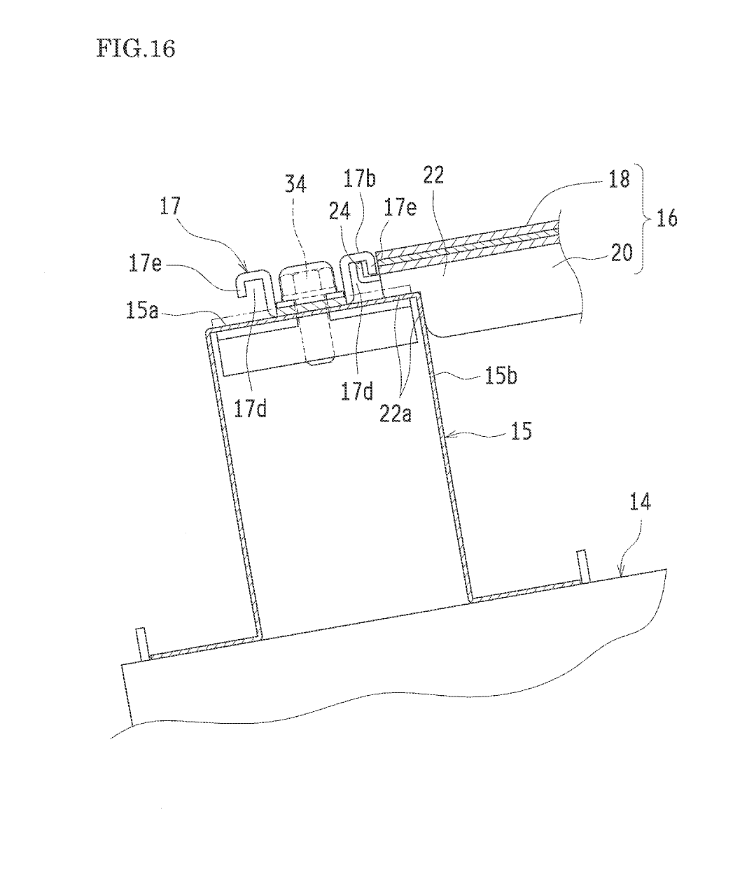

Specifically, a plurality of concrete foundations 11 are laid on the ground at regular intervals. Base crosspieces 12, each being fixed on a top face 111 of each concrete foundation 11, are provided next to each other at regular intervals. Arms 13 are connected to, and extend upright from, rear ends 121 of the base crosspieces 12. Vertical crosspieces 14 are fixed in an inclined manner on front ends 122 of the base crosspieces 12 and on top ends of the arms 13. Further, three horizontal crosspieces 15 are arranged orthogonally to the vertical crosspieces 14 and laid on the vertical crosspieces 14. In other words, the horizontal crosspieces 15 are arranged at different heights from each other according to the inclination of the vertical crosspieces 14. Each solar cell module 16 is mounted in an inclined manner by placing both longitudinal end portions thereof on adjacent horizontal crosspieces 15. The end portions of each solar cell module 16 are fixedly held by guide supports 17 (see FIG. 15, FIG. 16, etc.) attached at predetermined positions on the horizontal crosspieces 15.

In the photovoltaic system of this configuration, a plurality of solar cell modules 16 are placed in a row across the bottom horizontal crosspiece 15 and the center horizontal crosspiece 15, and a plurality of solar cell modules 16 are placed in a row across the center horizontal crosspiece 15 and the top horizontal crosspiece 15. Namely, a plurality of solar cell modules 16 are placed in two rows (a top row and a bottom row) on the three horizontal crosspieces 15. Between the two laterally adjacent vertical crosspieces 14, three solar cell modules 16 are placed in the top row, and three solar cell modules 16 are placed in the bottom row.

In the following description, the directions in which the concrete foundations 11 are laid next to each other in FIG. 1 are defined as X directions (horizontal or left-right directions), and the directions orthogonal to the X directions are defined as Y directions (vertical or front-back directions).

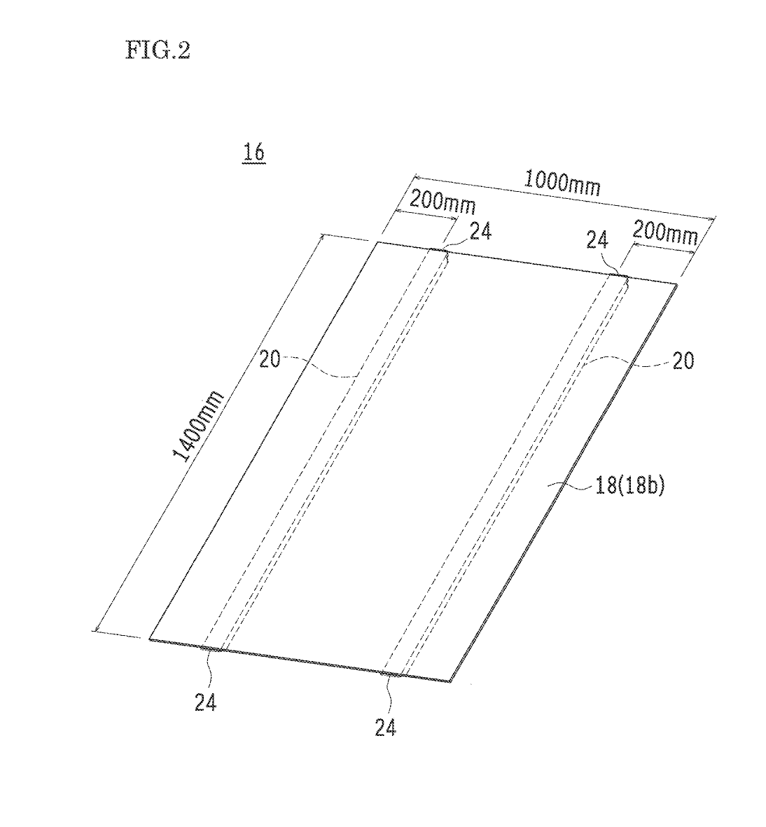

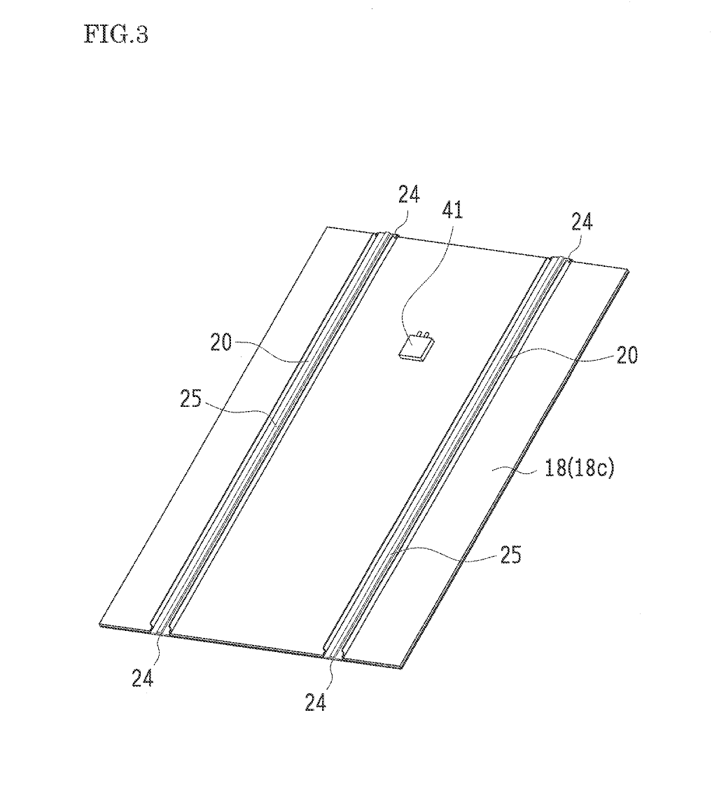

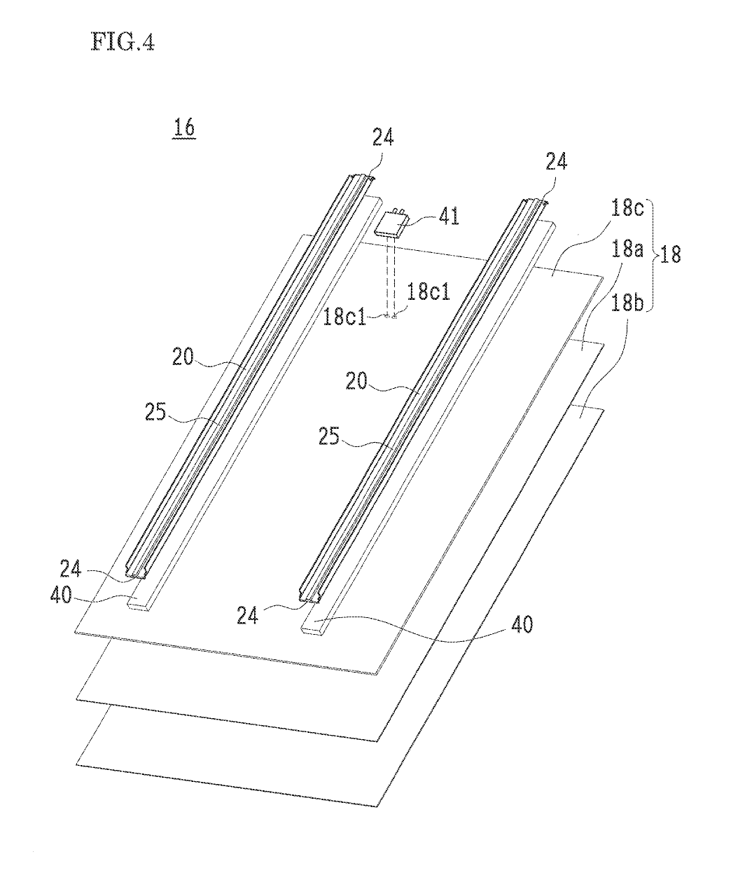

FIG. 2 to FIG. 4 show a configuration of one of the solar cell modules 16 according to the present embodiment. FIG. 2 is a perspective view as seen from the light-receiving face side. FIG. 3 is a perspective view as seen from a backside thereof, opposite to the light-receiving face side. FIG. 4 is an exploded perspective view as seen from the backside.

Each of the solar cell modules 16 according to the present invention is composed of a solar cell main body 18 and two support members 20 which also serve as mounting fittings for the rack 10.

As shown in FIG. 4, the solar cell main body 18 has a laminated glass structure composed of a solar cell I 8a for photoelectrically converting sunlight, a light-receiving glass 18b, and a backside glass 18c, with the solar cell 18a being laid between the light-receiving glass 18b and the backside glass 18c. On the surface of the backside glass 18c, elongated support members 20 are fixedly arranged to extend along a longitudinal direction of the solar cell main body 18. The shape of the support members 20 allows the solar cell main body 18 to be mounted on the rack 10. For each solar cell main body, two support members 20 are arranged parallel to each other, spaced from each other in a width direction of the solar cell main body 18 by a predetermined interval, and symmetrical about the center line which passes the widthwise center of the solar cell main body 18. The positions of these support members 20 are inwardly distant from longitudinal sides of the solar cell main body 18 by a certain distance. Specifically, each solar cell main body 18 is rectangular in plan view, with a length of about 1400 mm and a width of about 1000 mm. The support members 20 are positioned inwardly from longitudinal sides of the solar cell main body 18 by about 200 mm (but not limited to 200 mm). With two support members 20 being arranged in the width direction of each solar cell main body 18, when the solar cell module 16 is mounted on the rack 10, the solar cell module 16 can be fixedly mounted on the rack 10 in a stable manner without being wobbly in the width directions (horizontal or left-right directions). Besides, since the support members 20 are positioned inwardly from the longitudinal sides of the solar cell main body 18 by about 200 mm, the weight of the solar cell main body 18 imposed on the support members 20 can be distributed in a proper balance.

Further, the support members 20 are fixedly bonded on the surface of the backside glass 18c of the solar cell main body 18 by an adhesive material 40. Various types of adhesive agents may be used as the adhesive material 40, and a two-component silicone adhesive is used in the present embodiment. Use of a two-component silicone adhesive as the adhesive material 40 has a following advantage. For example, after the solar cell module is mounted on the rack 10, even if the support members 20 and the solar cell main body 18 may undergo thermal shrinkage or thermal expansion due to an influence (temperature change) in the surrounding environment, the two-component silicone adhesive can mitigate the stress due to the difference in thermal expansion coefficient between the support members 20 and the solar cell main body 18 (specifically, the backside glass 18c). Namely, it is possible to reduce the load stress on the solar cell main body 18 and to prevent cracks or other damages. As the adhesive material 40, one-component silicone adhesive is replaceable with a two-component silicone adhesive to achieve a similar effect.

Also illustrated in FIG. 3 and FIG. 4 is a terminal box 41 for allowing output lead wires (not shown) of the solar cell 18a to be pulled out from openings 18c1 in the backside glass 18c and for making electrical connection.

Next, the description turns to the shape of the support members 20.

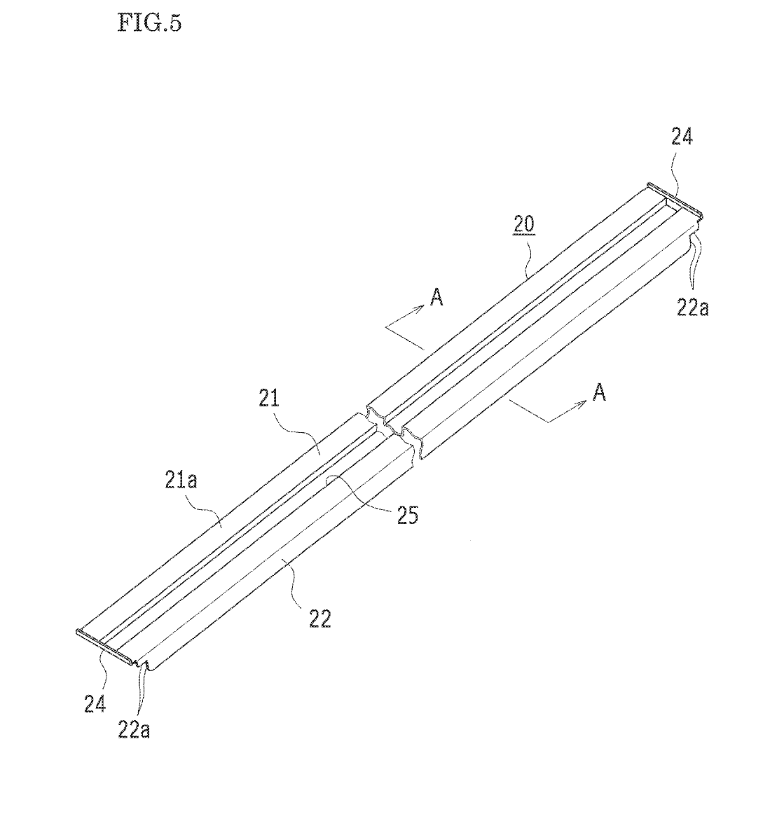

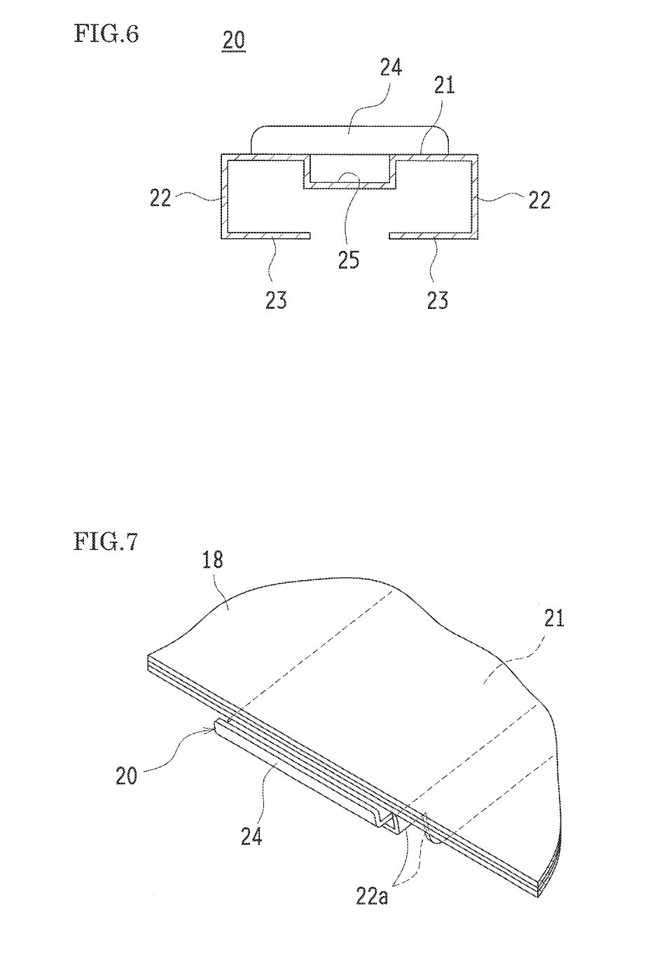

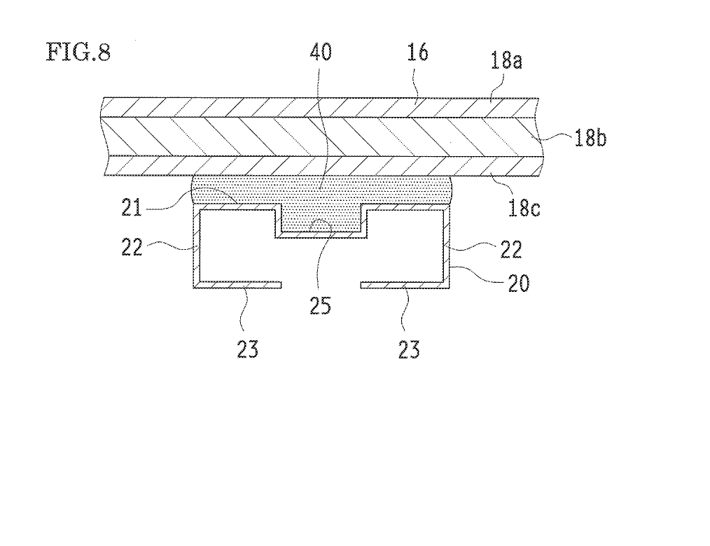

FIG. 5 is a perspective view of a support member 20. FIG. 6 is a cross section taken along the line A-A in FIG. 5. FIG. 7 is a perspective view of the solar cell module 16, showing around an end of the support member 20 on an enlarged scale. FIG. 8 is a cross section in which the support member 20 is bonded on the backside glass of the solar cell main body.

Each of the support members 20 according to the present embodiment has an elongated main plate 21, side plates 22 which are bent down from longitudinal sides of the main plate 21, bottom plates 23 which are bent inwardly from lower ends of the side plates 22, and L-shaped engagement portions 24 which are bent up from longitudinal ends of the main plate 21. The lateral cross section of the support member 20 is substantially in the form of a lip channel steel. When the support members 20 are attached to the rack 10 and hold the entire solar cell main body 18, the above-described structure can keep the strength of the support members 20 sufficiently against the load of the solar cell main body 18, and can withstand long-term use.

Further in the support member 20, as shown in FIG. 7, the above-mentioned engagement portions 24 are formed at longitudinal ends of the main plate 21 which protrude from longitudinal ends of the solar cell main body 18. The engagement portions 24 are shaped in the form of letter L to be engageable with the guide supports 17 on the rack 10.

Since the engagement portions 24 at the ends of the support member 20 protrude from the ends of the solar cell main body 18, when the solar cell module 16 is mounted on the rack 10, the engagement portions 24 of the support member 20 can be visually easily positioned at the mounting positions on the rack 10. As a result, it is possible to improve work efficiency in mounting and fixing the solar cell module 16 on the rack 10. Besides, since the protruding engagement portions 24 of the support member 20 are shaped to engage with mounting fittings on the rack 10 which are employed to mount the solar cell module 16 on rack 10, it is possible to reduce the number of mounting fittings required to mount the components on the rack 10. Eventually, it is possible to reduce the procedures in the mounting operation and to simplify the mounting operation.

In the above-mentioned configuration, the support member 20 is provided with a recess 25, as shown in FIG. 5, in an adhesion surface 21a of the main plate 21 on which the adhesive material 40 is applied (a surface of the main plate 21 to be bonded to the backside glass 18c). In the present embodiment, the recess 25 is shaped in the form of a groove. As shown in FIG. 8, the recess 25 provided in the adhesion surface 21a of the main plate 21 can ensure the thickness of the adhesive material 40 applied between the adhesion surface 21a of the support member 20 and the backside glass 18c, and can thereby enhance the adhesion force.

More specifically, the recess 25 extends along a longitudinal direction of the support member 20 (namely, the main plate 21) on a central portion thereof in the width direction. The recess 25 extending along a longitudinal direction of the support member 20 over a whole length thereof can ensure uniform adhesion strength in the longitudinal directions of the solar cell module 16.

The following description relates to alternative configuration examples of the recess.

### ALTERNATIVE CONFIGURATION EXAMPLE 1

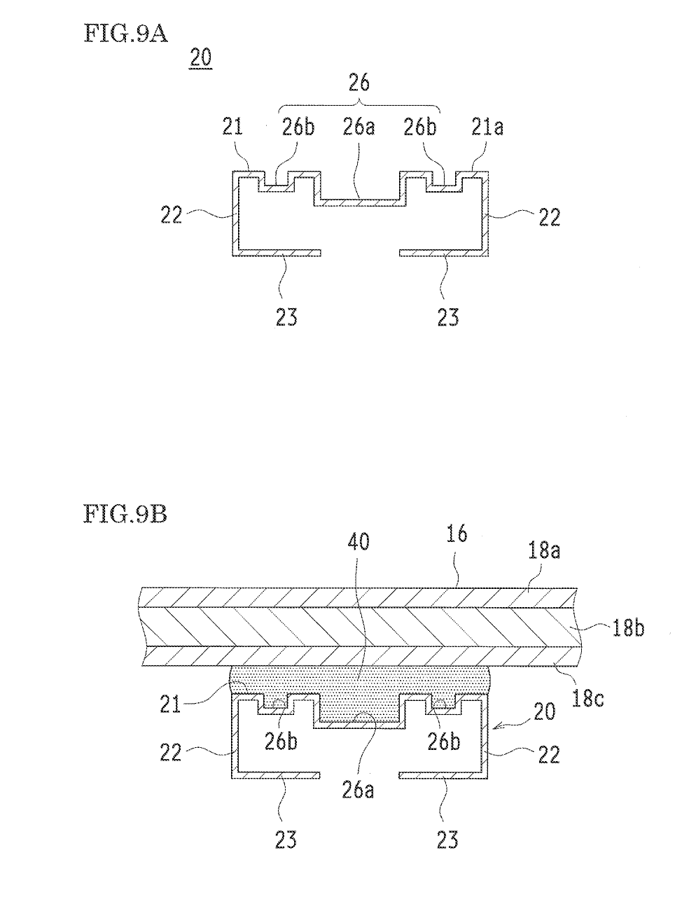

FIG. 9A is a cross section of a recess according to Alternative Configuration Example 1. FIG. 9B is a cross section in which the support member 20 is fixedly bonded on the backside glass 18c of the solar cell module 16.

The recess 26 according to Alternative Configuration Example 1 is composed of a first recess 26a having a deeper groove shape and second recesses 26b each having a shallower groove shape (than the first recess 26a). The first recess 26a is formed on the central portion of the support member 20 in the width direction orthogonal to the longitudinal direction. The second recesses 26b are respectively formed on both sides of the first recess 26a and extend parallel thereto. As shown in FIG. 9B, owing to the recess 26 composed of the deeper first recess 26a and the shallower second recesses 26b respectively formed on both sides thereof, when the support member 20 is bonded to the backside glass 18c, the adhesive material 40 which runs over from the first recess 26a can be stopped in the second recesses 26b. Thus, it is possible to prevent the adhesive material from running over from the longitudinal edges of the support member 20.

### ALTERNATIVE CONFIGURATION EXAMPLE 2

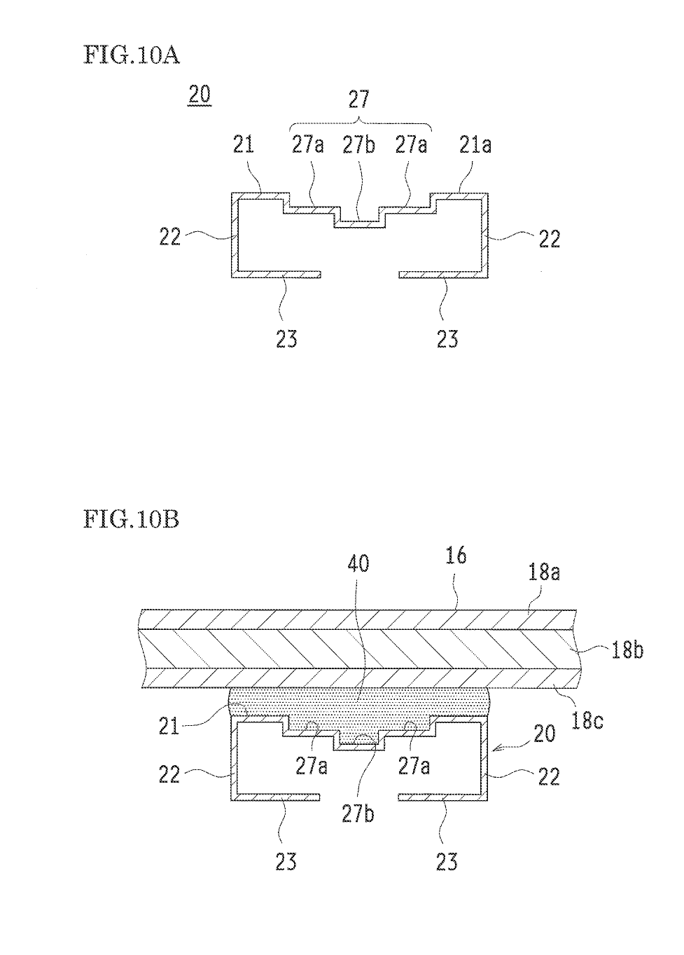

FIG. 10A is a cross section of a recess according to Alternative Configuration Example 2. FIG. 10B is a cross section in which the support member 20 is fixedly bonded on the backside glass 18c of the solar cell module 16.

The recess 27 according to Alternative Configuration Example 2 is composed of a first recess 27a having a groove shape and a second recess 27b having a deeper groove shape (than the first recess 27a). The first recess 27a is formed on the central portion of the support member 20 in the width direction orthogonal to the longitudinal direction. The second recess 27b is formed in the bottom surface of the first recess 27a. As shown in FIG. 10B, owing to the recess 27 composed of the first recess 27a and the deeper second recess 27b, the thickness of the adhesive material 40 applied to the adhesion surface 21a of the support member 20 can be ensured better by the second recess 27b, and hence the adhesion force can be further enhanced.

### ALTERNATIVE CONFIGURATION EXAMPLE 3

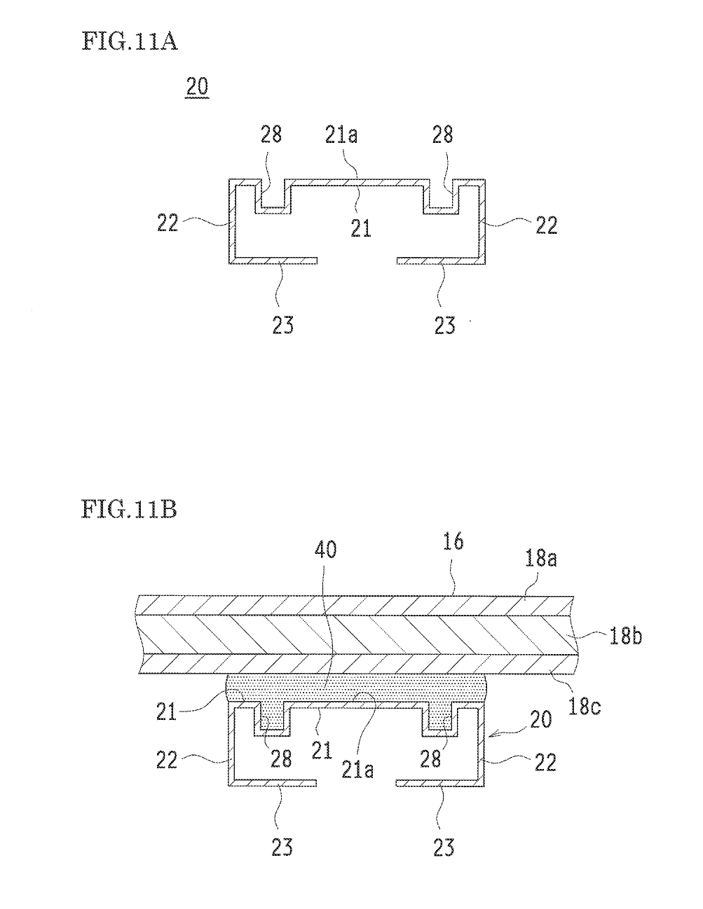

FIG. 11A is a cross section of recesses according to Alternative Configuration Example 3. FIG. 11B is a cross section in which the support member 20 is fixedly bonded on the backside glass 18c of the solar cell module 16.

The recesses 28 according to Alternative Configuration Example 3 are formed on both edge portions of the support member 20 in the width direction that is orthogonal to the longitudinal direction. As shown in FIG. 11B, the groove-shaped recesses 28 formed on the widthwise edge portions can ensure uniform adhesion strength in the width directions of the solar cell module.

### ALTERNATIVE CONFIGURATION EXAMPLE 4

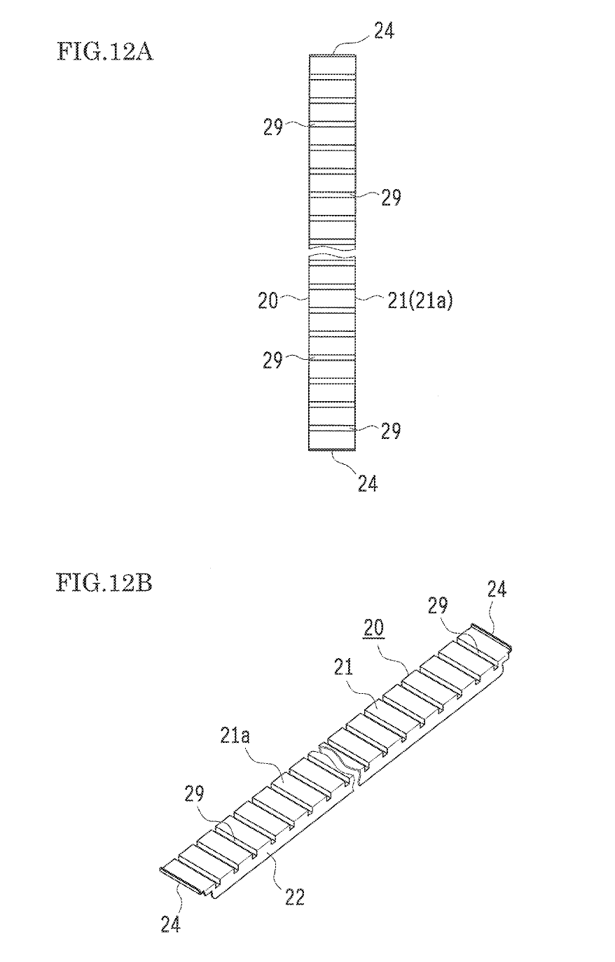

FIG. 12A is a plan view of recesses according to Alternative Configuration Example 4. FIG. 12B is a perspective view thereof.

A plurality of recesses 29 according to Alternative Configuration Example 4 are provided to align in the lateral direction of the support member 20 that is orthogonal to the longitudinal direction of the support member 20, being spaced from each other at a predetermined interval. Owing to the groove-shaped recesses 29 which are provided in the lateral direction of the support member 20 that is orthogonal to the longitudinal direction of the support member 20, it is possible to ensure sufficient strength to withstand the stress due to a difference in thermal expansion between the support member 20 and the backside glass 18c caused by the heat or the like after the solar cell module 16 is mounted on the rack 10.

### ALTERNATIVE CONFIGURATION EXAMPLE 5

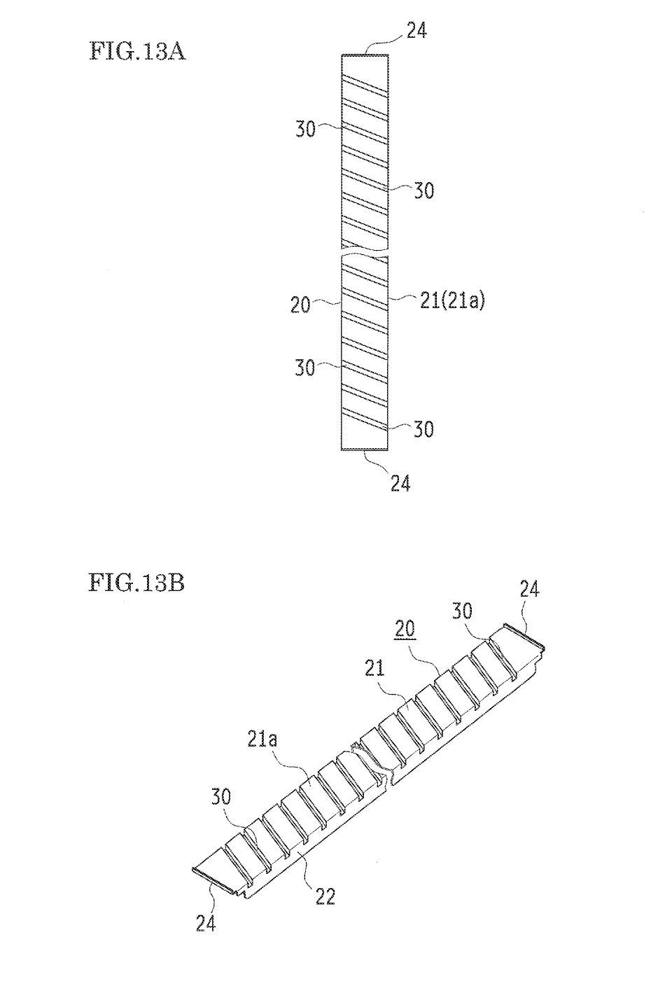

FIG. 13A is a plan view of recesses according to Alternative Configuration Example 5. FIG. 13B is a perspective view thereof.

A plurality of recesses 30 according to Alternative Configuration Example 5 are provided to align obliquely to the longitudinal direction of the support member 20, being spaced from each other at a predetermined interval. Owing to the groove-shaped recesses 30 which are provided to align obliquely to the longitudinal direction of the support member 20, it is possible to ensure sufficient strength to withstand the stress due to a difference in thermal expansion between the support member 20 and the backside glass 18c caused by the heat or the like after the solar cell module 16 is mounted on the rack 10.

### ALTERNATIVE CONFIGURATION EXAMPLES 6 AND 7

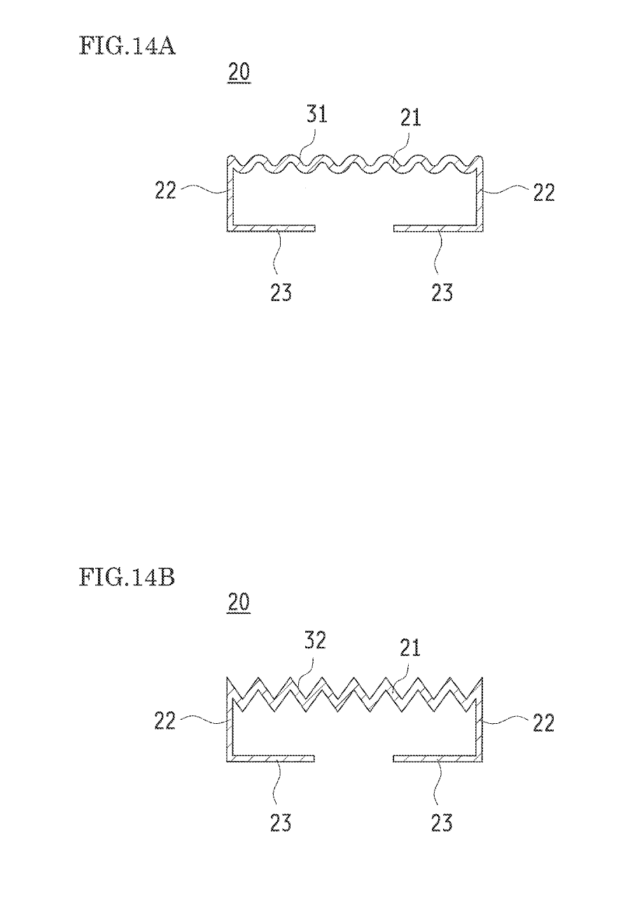

FIGS. 14A and 14B are cross sections of recesses according to Alternative Configuration Examples 6 and 7, respectively. According to Alternative Configuration Example 6 shown in FIG. 14A, the cross sectional shape of the recesses 31 is a wavy shape repeated in the lateral direction (width direction) of the main plate 21. According to Alternative Configuration Example 7 shown in FIG. 14B, the cross sectional shape of the recesses 32 is a triangular shape repeated in the width direction (lateral direction) of the main plate 21. The cross sectional shape of the recesses should not be limited to the wavy or triangular shape as described above, but may be, for example, a trapezoidal shape or other various shapes. In other words, in Alternative Configuration Examples 6 and 7, the bottom surfaces of the recesses 31, 32 have bumpy shapes. The recesses 31, 32 whose cross sectional shapes are designed in this manner (i.e. the bottom surfaces of the recesses have bumpy shapes) can not only ensure the thickness of the adhesive material 40 applied to the adhesion surface 21 a of the support member 20, but can also increase an adhesion area between the support member 20 and the adhesive material 40 to achieve a greater adhesion force.

In the above-described embodiment and Alternative Configuration Examples 1 to 7, each recess is supposed to be a groove, but the recess(es) should not necessarily be a groove. As far as the adhesion surface 21a of the support member 20 has a difference in height (a difference in level), the object of the present invention is achieved.

For example, as the bumpy shape, a multitude of protrusions in the form of, for example, triangular pyramids, quadrangular pyramids, or cylinders may be provided in the bottom surface of the recess, on the entire adhesion surface 21a of the main plate 21. Such bumpy shapes can also impart a difference in height (a difference in level) to the adhesion surface 21a of the support member 20, thereby ensuring the thickness of the adhesive material 40 applied to the adhesion surface 21a of the support member 20. Further, such bumpy shapes can increase an adhesion area between the support member 20 and the adhesive material 40 and can thereby enhance the adhesion force.

Next referring to FIG. 15 and FIG. 16, the structure for supporting the solar cell module 16 by the guide supports 17 on the horizontal crosspieces 15 is briefly described. It should be noted, however, the support structure is not a characteristic feature of the present invention, and that a variety of support structures are applicable. Hence, the support structure shown in FIG. 15 and FIG. 16 should be understood as a mere example.

As shown in FIG. 15 and FIG. 16, fitting grooves 17d on both sides of each guide support 17 extend parallel to the horizontal crosspieces 15, with gaps being formed between hooks 17e of the fitting grooves 17d and the main plate 15a of the horizontal crosspiece 15. One of the engagement portions 24 of the support member 20 in the solar cell module 16 is caught in one of the fitting grooves 17d through a gap between the hook 17e of the fitting groove 17d and the main plate 15a of the horizontal crosspiece 15, so that the engagement portion 24 of the support member 20 is fitted (engaged) in the fitting groove 17d.

In addition, one of the side plates 22 of the support member 20 abuts on the stopper 17f of the guide support 17, and the abutment portion 22a of the support member 20 abuts on the main plate 15a and one of the side plates 15b of the horizontal crosspiece 15 (abuts on a corner of the horizontal crosspiece 15).

Accordingly, each longitudinal end of the support member 20 is supported by the engagement portion 24 of the support member 20 which fits in the fitting groove 17d of the guide support 17, and thereby each end portion of the solar cell module 16 is supported on the main plate 15a of the horizontal crosspiece 15. In this state, the solar cell module 16 is positioned, with one of the side plates 22 of the support member 20 abutting on the stopper 17f of the guide support 17, and the abutment portion 22a of the support member 20 abutting on a corner of the horizontal crosspiece 15.

Namely, while each abutment portion 22a of the side plate 22 of the support member 20 abuts in a fitting manner on the main plate 15a and one of the side plates 15b which together constitute a corner of the horizontal crosspiece 15, longitudinal movement (movement in Y directions in FIG. 1) of the support member 20 can be reliably restricted. Besides, while each engagement portion 24 of the support member 20 fits in the fitting groove 17d of the guide support 17, vertical movement relative to the mounting surface of the rack 10 can be also restricted.

Further, while the side plate 22 of the support member 20 abuts on the stopper 17f of the guide support 17, it is possible to block the sliding movement (movement in X directions in FIG. 1) of the support member 20 and also to block the sliding movement of the solar cell module 16. Additionally, as shown in FIG. 15 and FIG. 16, each guide support 17 is fixed on the horizontal crosspiece 15 by a bolt 34.

The present invention can be embodied and practiced in other different forms without departing from the spirit and essential characteristics of the present invention. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

The present application claims priority to Japanese Patent Application No. 2012-006943, filed on Jan. 17, 2012, the contents of which are incorporated herein by reference in its entirety.

### REFERENCE SIGNS LIST

10 rack
11 concrete foundation
12 base crosspiece
13 arm
14 vertical crosspiece
15 horizontal crosspiece
15a main plate
15b side plate
16 solar cell module
17 guide support
17d fitting groove
17e hook
17f stopper
18 solar cell main body
18a solar cell
18b light-receiving glass
18c backside glass
20 support member
21 main plate
21a adhesion surface
22 side plate
22a abutment portion
23 bottom plate
24 engagement portion
25, 26, 27, 28, 29, 30, 31, 32 recess
26a, 27a first recess
26b, 27b second recess
34 bolt
40 adhesive material

1. A solar cell module comprising an elongated support member and a solar cell main body having a laminated glass structure,
wherein the solar cell main body comprises a light-receiving glass, a backside glass, and a solar cell for photoelectrically converting sunlight, the solar cell being laid between the light-receiving glass and the backside glass,
the support member is fixedly bonded on a surface of the backside glass by an adhesive material, and
the support member has a recess formed in an adhesion surface of the support member to be bonded to the backside glass.

2. The solar cell module according to claim 1, wherein the recess is provided to extend along a longitudinal direction of the support member.

3. The solar cell module according to claim 2, wherein the recess comprises a deeper first recess formed on a central portion of the support member in a width direction that is orthogonal to the longitudinal direction, and a pair of shallower second recesses respectively formed on both sides of the first recess and parallel to the first recess.

4. The solar cell module according to claim 2, wherein the recess comprises a first recess formed on a central portion of the support member in a width direction that is orthogonal to the longitudinal direction, and a second recess formed in a bottom surface of the first recess and being deeper than the first recess.

5. The solar cell module according to claim 2, wherein the recess comprises a pair of recesses respectively formed on both edge portions of the support member in a width direction that is orthogonal to the longitudinal direction.

6. The solar cell module according to claim 1, wherein the recess comprises a plurality of recesses which align transversely or obliquely relative to the longitudinal direction of the support member.

7. The solar cell module according to claim 6, wherein the plurality of recesses are spaced from each other at a predetermined interval over a whole length in the longitudinal direction of the support member.

8. The solar cell module according to claim 1, wherein the recess has a groove shape.

9. The solar cell module according to claim 1, wherein a bottom surface of the recess has a bumpy shape.

10. The solar cell module according to claim 1, wherein the adhesive material is a one-component or two-component silicone adhesive.
